(19) United States
(12) Patent Application Publication
(10) Pub. No.: US 2012/0224719 A1
(43) Pub. Date: Sep. 6, 2012

(54) VIBRATION CONTROL

(75) Inventor: Fredrik Johansson, Malmo (SE)

(73) Assignee: SONY MOBILE COMMUNICATIONS AB, Lund (SE)

(21) Appl. No.: 13/392,918

(22) PCT Filed: Mar. 4, 2011
(86) PCT No.: PCT/IB11/50934

§ 371 Date: Feb. 28, 2012

(51) Int. Cl. H03G 5/00

(52) U.S. Cl. 381/98

(57) ABSTRACT

A device may include a speaker, a vibration device and logic. The speaker may be configured to output audio signals. The logic may be configured to perform audio spectrum analysis associated with the audio signals, and synchronize output of the vibration device with the audio signals output by the speaker based on the audio spectrum analysis. The vibration device may also be configured to vibrate at a number of different frequencies based on the audio spectrum analysis.

### TECHNICAL FIELD OF THE INVENTION

The invention relates generally to providing alerts to users and, more particularly, to synchronizing a vibration alert with an audio output.

### DESCRIPTION OF RELATED ART

Electronic devices, such as cellular telephones, may utilize a vibration mechanism in combination with an audio signal to notify a user of an event. The vibration mechanism is useful in attracting the user's attention to an event, such as an incoming call. The use of a vibration mechanism is particularly useful and convenient when the sound of an audio signal may prove disruptive, such as when the user is in a meeting, at the library, etc. Additionally, in an environment where the volume of the device is set relatively low, the audible notification may be augmented by activating the vibration mechanism to increase the chances of attracting the user's attention.

### SUMMARY

According to one aspect, a method is provided. The method includes analyzing audio that is output by a first device; determining, for a first portion of the audio having a first range of frequencies, whether output associated with one of the first range of frequencies is greater than a first threshold value; and determining, for a second portion of the audio having a second range of frequencies, whether output associated with one of the second range of frequencies is greater than a second threshold value. The method also includes outputting, by the first device, vibrations having a first frequency in response to determining that the output associated with one of the first range of frequencies is greater than the first threshold value, and outputting, by the first device, vibrations having a second frequency in response to determining that the output associated with one of the second range of frequencies is greater than the second threshold value

Additionally, the first frequency may be lower than the second frequency.

Additionally, the first range of frequencies may be lower than the second range of frequencies.

Additionally, the determining whether output associated with one of the first range of frequencies is greater than a first threshold value may comprise identifying whether output associated with one of the first range of frequencies reaches or exceeds a predetermined decibel value

Additionally, the determining whether output associated with one of the second range of frequencies is greater than a second threshold value may comprise identifying whether output associated with one of the second range of frequencies reaches or exceeds the predetermined decibel value.

Additionally, the method may include generating a first vibration trigger in response to determining that audio output within the first range of frequencies is greater than the first threshold value; and generating a second vibration trigger in response to determining that audio output within the second range of frequencies is greater than the second threshold value, wherein the first threshold value is equal to the second threshold value.

Additionally, the method may include controlling a vibrator motor to rotate at a first speed for a first period of time in response to the first vibration trigger; and controlling the vibrator motor to rotate at a second speed for a second period of time in response to the second vibration trigger, wherein the first speed is different than the second speed.

Additionally, the audio may comprise a song, a ringtone, an alarm or an audio portion of a video file.

Additionally, the device may comprise a mobile terminal.

According to another aspect, a device is provided. The device may include a speaker configured to output audio signals, at least one vibration device, and logic. The logic is configured to perform audio spectrum analysis associated with the audio signals, and synchronize output of the at least one vibration device with the audio signals output by the speaker based on the audio spectrum analysis. The at least one vibration device is configured to vibrate at a plurality of different frequencies based on the audio spectrum analysis.

Additionally, when synchronizing output, the logic may be configured to determine, for a first portion of the audio spectrum having a first range of frequencies, whether an output associated with one of the first range of frequencies has at least a first output level, determine, for a second portion of the audio spectrum having a second range of frequencies, whether an output associated with one of the second range of frequencies has at least a second output level, transmit a first signal to the at least one vibration device in response to determining that an output associated with one of the first ranges of frequencies has at least the first output level, and transmit a second signal to the at least one vibration device in response to determining that an output associated with one of the second ranges of frequencies has at least the second output level.

Additionally, the at least one vibration device may comprise a first vibration device, where the first vibration device is configured to vibrate at a first frequency for a first duration of time in response to the first signal, and vibrate at a second frequency for a second duration of time in response to the second signal, wherein the second frequency is higher than the first frequency.

Additionally, the first and second durations of time may be based on the audio spectrum analysis.

Additionally, the first range of frequencies may be lower than the second range of frequencies.

Additionally, the first output level may correspond to a predetermined decibel value and the second output level may correspond to the predetermined decibel value.

Additionally, the at least one vibration device may comprise a first vibration device including a motor, wherein the motor is configured to rotate at a first speed in response to a first vibration trigger that is generated based on the audio spectrum analysis, and rotate at a second speed in response to a second vibration trigger that is generated based on the audio spectrum analysis, wherein the first speed is slower than the second speed.

Additionally, the logic may be configured to perform the audio spectrum analysis in real-time.

Additionally, the at least one vibration device may comprise a first vibration device configured to vibrate at a first frequency based on the audio spectrum analysis, and a second vibration device configured to vibrate at a second frequency based on the audio spectrum analysis, wherein the second frequency is greater than the first frequency.

Additionally, the audio may comprise an alarm, a song, music or a ringtone and the device may comprise a mobile terminal.

According to a further aspect, a computer-readable memory device having stored thereon sequences of instructions is provided. The instructions, when executed by at least one processor, cause the at least one processor to perform audio spectrum analysis associated with audio signals output by a device; generate a first vibration trigger based on the audio spectrum analysis, the first vibration trigger corresponding to an audio output within a first band of frequencies that has exceeded a predetermined level; generate a second vibration trigger based on the audio spectrum analysis, the second vibration trigger corresponding to an audio output within a second band of frequencies that has exceeded the predetermined level; and forward the first and second vibration triggers to a vibration unit within the device.

### BRIEF DESCRIPTION OF THE DRAWINGS

Reference is made to the attached drawings, wherein elements having the same reference number designation may represent like elements throughout.

FIG. 1 is a diagram of an exemplary device in which methods and systems described herein may be implemented;

FIG. 2 is a functional block diagram of exemplary components implemented in the device of FIG. 1;

FIG. 3 is a block diagram of components implemented in the device of FIG. 1 according to an exemplary implementation;

FIGS. 4A and 4B are exemplary diagrams associated with performing audio spectrum analysis of signals output by the device of FIG. 1; and

FIG. 5 is a flow diagram illustrating exemplary processing associated with synchronizing vibrations with audio output.

### DETAILED DESCRIPTION

The following detailed description of the invention refers to the accompanying drawings. The same reference numbers in different drawings identify the same or similar elements. Also, the following detailed description does not limit the invention. Instead, the scope of the invention is defined by the appended claims and equivalents.

### Exemplary System

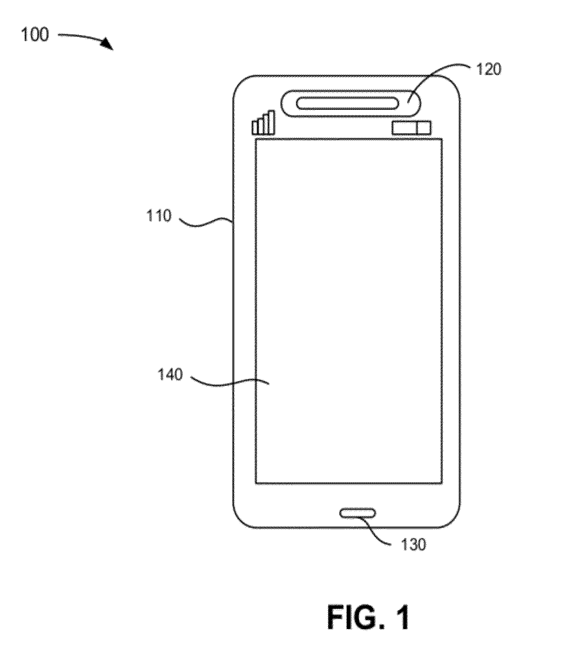

FIG. 1 is a diagram of an exemplary user device 100 in which methods and systems described herein may be implemented. In an exemplary implementation, user device 100 may be a mobile terminal. As used herein, the term “mobile terminal” may include a cellular radiotelephone with or without a multi-line display; a Personal Communications System (PCS) terminal that may combine a cellular radiotelephone with data processing, facsimile and data communications capabilities; a personal digital assistant (PDA) that can include a radiotelephone, pager, Internet/Intranet access, Web browser, organizer, calendar and/or a global positioning system (GPS) receiver; and a conventional laptop and/or palmtop receiver or other appliance that includes a radiotelephone transceiver. Mobile terminals may also be referred to as “pervasive computing” devices. It should also be understood that systems and methods described herein may also be implemented in other devices that display information of interest and allow users to interact with the displayed information. For example, user device 100 may include a personal computer (PC), a laptop computer, a tablet computer, a netbook, a media playing device (e.g., an MPEG audio layer 3 (MP3) player, a video game playing device, etc.), a global positioning system (GPS) device, etc.

Referring to FIG. 1, user device 100 may include a housing 110, a speaker 120, a microphone 130 and a display 140. Housing 110 may protect the components of user device 100 from outside elements. Speaker 120 may provide audible information to a user of user device 100. For example, speaker 120 may output music, ringtones, etc. Microphone 130 may receive audible information from the user of user device 100.

Display 140 may provide visual information to the user. For example, display 140 may provide information regarding incoming or outgoing telephone calls, electronic mail (e-mail), instant messages, short message service (SMS) messages, etc. Display 140 may also display information (not shown) regarding various applications stored in user device 100, such as an email program, a camera program/function, a phone book/contact list, an Internet browser used to access/download content (e.g., news or other information), etc. In an exemplary implementation, display 140 may be a touch screen display device that allows a user to enter commands and/or information via a finger, a stylus, a mouse, a pointing device, or some other device. For example, display 140 may be a resistive touch screen, a capacitive touch screen, an optical touch screen, an infrared touch screen, a surface acoustic wave touch screen, or any other type of touch screen device that registers an input based on a contact with the screen.

Display 140 may also provide control buttons and/or a keypad, such as a soft telephone keypad (not shown), that permit the user to interact with user device 100 to cause user device 100 to perform one or more operations, such as place a telephone call, access information, etc.

In an exemplary implementation, user device 100 may include one or more mechanisms that alert the user to an alarm, an incoming telephone call or another event. For example, in one implementation, user device 100 may include one or more vibration mechanisms/units that alert the user to an event, such as an alarm or incoming call.

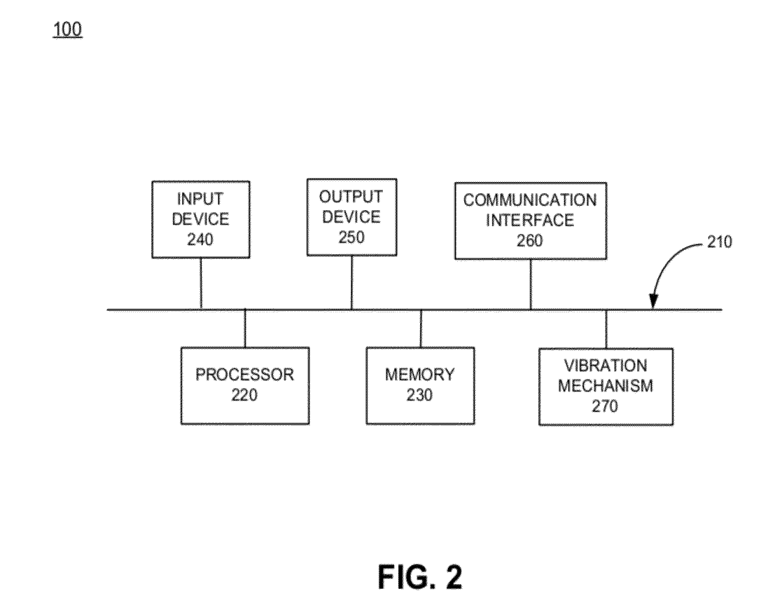

FIG. 2 is a diagram illustrating components of user device 100 according to an exemplary implementation. User device 100 may include bus 210, processor 220, memory 230, input device 240, output device 250, communication interface 260 and vibration mechanism 270. Bus 210 permits communication among the components of user device 100. One skilled in the art would recognize that user device 100 may be configured in a number of other ways and may include other or different elements. For example, user device 100 may include one or more modulators, demodulators, encoders, decoders, etc., for processing data.

Processor 220 may include a processor, microprocessor, an application specific integrated circuit (ASIC), field programmable gate array (FPGA) or other processing logic. Processor 220 may execute software instructions/programs or data structures to control operation of user device 100.

Memory 230 may include a random access memory (RAM) or another type of dynamic storage device that stores information and instructions for execution by processor 220; a read only memory (ROM) or another type of static storage device that stores static information and instructions for use by processor 220; a flash memory (e.g., an electrically erasable programmable read only memory (EEPROM)) device for storing information and instructions; a hard disk drive (HDD); and/or some other type of magnetic or optical recording medium and its corresponding drive. Memory 230 may also be used to store temporary variables or other intermediate information during execution of instructions by processor 220. Instructions used by processor 220 may also, or alternatively, be stored in another type of computer-readable medium accessible by processor 220. A computer-readable medium may include one or more memory devices.

Input device 240 may include mechanisms that permit an operator to input information to user device 100, such as microphone 130, a keypad, control buttons, a keyboard (e.g., a QWERTY keyboard, a Dvorak keyboard, etc.), a gesture-based device, an optical character recognition (OCR) based device, a joystick, a touch-based device, a virtual keyboard, a speech-to-text engine, a mouse, a pen, a stylus, voice recognition and/or biometric mechanisms, etc. In an exemplary implementation, display 140 may be a touch screen display that acts as an input device.

Output device 250 may include one or more mechanisms that output information to the user, including a display, such as display 140, a printer, one or more speakers, such as speaker 120, etc. As described above, in an exemplary implementation, display 140 may be a touch screen display. In such an implementation, display 140 may function as both an input device and an output device.

Communication interface 260 may include a transceiver that enables user device 100 to communicate with other devices and/or systems. For example, communication interface 260 may include a modem or an Ethernet interface to a LAN. Communication interface 260 may also include mechanisms for communicating via a network, such as a wireless network. For example, communication interface 260 may include one or more radio frequency (RF) transmitters, receivers and/or transceivers and one or more antennas for transmitting and receiving RF data via a network.

Vibration mechanism 270 (also referred to as vibration unit 270 or vibrator 270) may include a mechanism that produces vibrations that may be sensed by a user of user device 100. In an exemplary implementation, vibrator 270 may include a motor, a gear and a small weight attached/mounted to the gear. When the motor turns the gear, the weight attached to the gear causes a vibration that may be felt by the user holding or carrying user device 100. In an exemplary implementation, vibrator 270 may include a control mechanism to allow vibrator 270 to vibrate at more than one frequency, as described in detail below.

User device 100 may provide a platform for a user to send and receive communications (e.g., telephone calls, electronic mail, text messages, multi-media messages, short message service (SMS) messages, etc.), play music, search the Internet, or perform various other functions. User device 100, as described in detail below, may also perform processing associated with providing different types of vibrations based on audio information output by user device 100. User device 100 may perform these operations in response to processor 220 executing sequences of instructions contained in a computer-readable medium, such as memory 230. Such instructions may be read into memory 230 from another computer-readable medium via, for example, communication interface 260. In alternative embodiments, hard-wired circuitry may be used in place of or in combination with software instructions to implement processes consistent with the invention. Thus, implementations described herein are not limited to any specific combination of hardware circuitry and software.

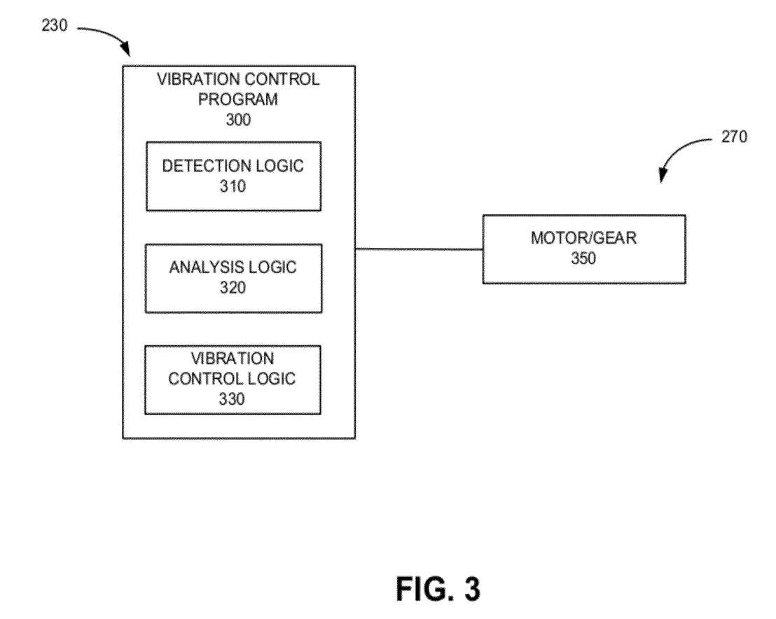

FIG. 3 is an exemplary block diagram of components implemented in user device 100 of FIG. 2. The components illustrated in FIG. 3 may be included in a single device/module, such as vibrator 270, or distributed among a number of devices/module. For example, some of the components illustrated in FIG. 3 may be stored in memory 230 and may be executed by processor 220 to control vibrator 270. For example, memory 230 may store a vibration control program 300 executed by processor 220 that controls vibrator 270.

Referring to FIG. 3, vibration control program 300 stored in memory 230 may include detection logic 310, analysis logic 320 and vibration control logic 330. Detection logic 310 may be configured to detect the occurrence of one or more different types of events. For example, detection logic 310 may detect and monitor events in real-time, such as detecting incoming telephone calls, detect other audio or data-related events, such as detecting incoming electronic mail messages, text messages, etc. Detection logic 310 may also detect events that satisfy predetermined conditions, such as an alarm or alert set for a particular time. Regardless of the source or type of event that is detected, detection logic 310 may forward information regarding a detected event to analysis logic 320 as a trigger for processing performed by analysis logic 320.

Analysis logic 320 after being notified of an event may perform analysis associated with the event. For example, analysis logic 320 may be notified of an alarm that is output by user device 100 at a particular time, an incoming telephone call received by user device 100, etc. In an exemplary implementation, analysis logic 320 may perform audio spectrum or frequency analysis of audio that is output by speaker 120 (e.g., music or a song associated with an alarm, a ringtone associated with a received telephone call, an audio portion of a video or multi-media file being executed or played by user device 100, etc.).

For example, analysis logic 320 may perform real-time audio spectrum analysis of music or ringtones played by user device 100. In one implementation, analysis logic 320 may identify one frequency band associated with low frequencies (e.g., base tones), and another frequency band associated with high frequencies (e.g., treble tones) In other implementations, analysis logic 320 may identify additional frequency bands, such as intermediate range frequency bands.

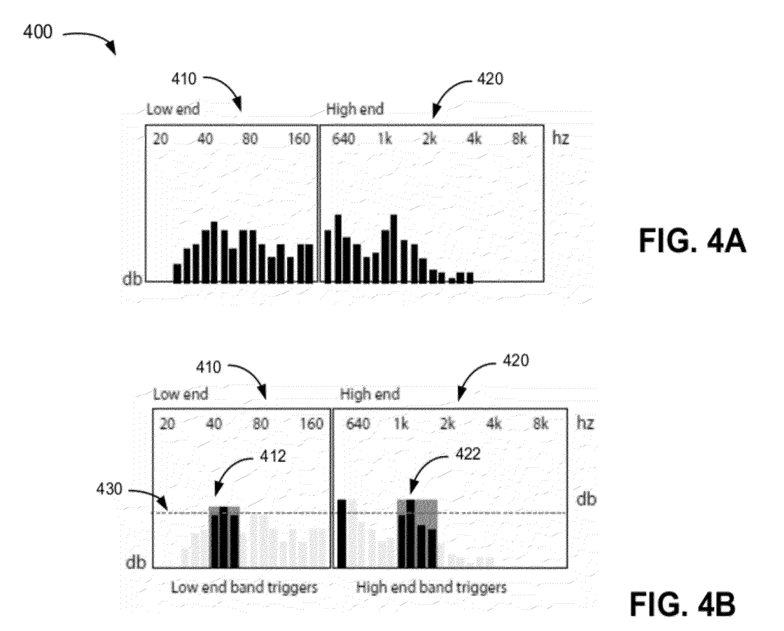

For example, FIG. 4A illustrates an exemplary audio spectrum 400 associated with output from user device 100. Referring to FIG. 4A, in an exemplary implementation, analysis logic 320 may divide the frequency/audio spectrum into a low frequency band of frequencies, labeled 410 in FIG. 4A, and a high frequency band of frequencies, labeled 420 in FIG. 4A. In one implementation, low frequency band 410 may range from 0 hertz (hz) to about 300 hz, and high frequency band 420 may range from 300 hz to 8000 hz and above.

Analysis logic 320 may set a trigger or threshold value to correspond to a particular decibel (dB) value associated with the audio output. For example, FIG. 4B illustrates a predetermined dB value labeled 430. The particular dB value for trigger/threshold value 430 may be set to correspond to portions of the audio that are more prominent than other portions, based on the dB output level. When analysis logic 320 detects that one of the frequencies in either the low end band or high end band achieves or exceeds trigger value 430, analysis logic 320 may forward a synchronization vibration signal to vibration control logic 330.

Vibration control logic 330 may receive information generated by analysis logic 320 regarding dB levels in audio that is output by user device 100. The input received by vibration control logic 330 may act as vibration triggers to “synchronize” audio output (e.g., ringtones, music, etc.) from speaker 120 to vibrations generated by vibration mechanism 270.

For example, as described above, vibration mechanism 270 may include a motor and gear, labeled 350 in FIG. 3, along with a weight attached to the gear (not shown). Vibration control logic 330 may signal vibration motor 350 to rotate the gear associated with vibration mechanism 270 at a first speed or frequency when the trigger value (e.g., value 430) is achieved within the lower band of frequencies (i.e., the band illustrated by 410). Vibration control logic 330 may also signal the vibration motor 350 to rotate the gear associated with vibration mechanism 270 at a second speed or frequency that is higher than the first speed or frequency when the trigger value (e.g., value 430) is achieved within the higher band of frequencies (i.e., the band illustrated by 420). This effectively causes vibration mechanism 270 to vibrate at a low frequency or a high frequency in synchronization with the audio output by user device 100. In some implementations, vibrator 270 may also be configured to vibrate for a particular duration each time a synchronization trigger is received. For example, vibrator 270 may vibrate for short bursts or durations, such as one to two seconds or less at the higher frequency or the lower frequency (depending on the control signal) each time the synchronization trigger is generated. Activating vibrator 270 for short durations or bursts allows the vibrations to be more closely synchronized to low or high frequency bursts in the audio.

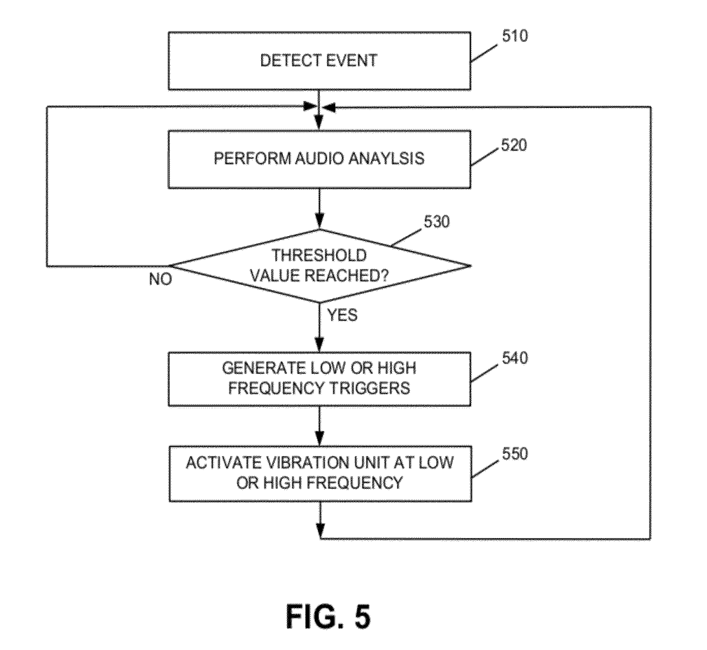

FIG. 5 illustrates exemplary processing associated with controlling the vibration of user device 100 to synchronize the vibration with another output. Processing may begin with user device 100 detecting an event (block 510). For example, detection logic 310 may detect a real-time event, such as an incoming call, the outputting of a ringtone, music, or any other audio signal, etc. In other instances, detection logic 310 may detected the initiation of a pre-programmed event stored within memory 230, such as an alert, or alarm scheduled by a user of user device 100.

In this example, assume that the event is an alarm set by the user, such as a wake-up alarm. In this case, user device 100 may output a default music selection/song or a customized music selection or song selected by the user. In either case, detection logic 310 may detect the event and forward a signal to analysis logic 320 indicating that the event has occurred.

Analysis logic 320 may begin performing real-time audio spectrum analysis of the audio output associated with the alarm (block 520). For example, analysis logic 320 may perform frequency/spectrum analysis for high and low frequency bands 410 and 420 illustrated in FIG. 4A. Analysis logic 320 may then determine whether output in either the low or high frequency band meets or exceeds a predetermined or threshold level (block 530). For example, referring to FIG. 4B, analysis logic 320 may determine whether the decibel level at any one of the frequencies meets threshold level 430 (FIG. 4B).

If the audio output associated with the alarm does not include an output at any of the frequencies in the audio spectrum that meet the threshold level 430 (block 530—no), processing continues with monitoring the audio spectrum of the alarm in real-time. If, however, analysis logic 320 identifies that output associated with one or more frequencies in the audio spectrum exceeds target/threshold level 430 (act 530—yes), analysis logic 320 forwards the information to vibration control logic 330. For example, analysis logic 320 may forward a synchronization trigger to vibration control logic 330.

Vibration control logic 330 may receive the trigger and determine whether the trigger is associated with low frequency band 410 or high frequency band 420. In this example, assume that one of more of the frequencies in the low frequency band 410 (highlighted and labeled 412 in FIG. 4B) exceed the threshold level. In one implementation, analysis logic 320 may forward information with the trigger indicating whether the trigger is associated with a low or high frequency band. In this case, vibration control logic 330 may receive the trigger and determine, based on the received information, whether the trigger is a high frequency trigger or a low frequency trigger.

Continuing with the example above in which the threshold/target 430 in the low frequency band 410 has been reached (e.g., at the area labeled 412 in FIG. 4), vibration control logic 330 may generate and send a vibration control trigger/signal to vibration mechanism 270 to indicate that vibration mechanism 270 should be vibrated at a low frequency (block 540). For example, vibration control logic 330 may send a signal to vibrator 270 (e.g., motor 350 of vibrator 270) to indicate that motor/gear 350 should be rotated at a relatively low frequency (e.g., 100 revolutions per minute (RPM), 150 RPM, etc.).

In response to the low frequency trigger, motor 350 may rotate the gear associated with vibrator 270 at the low frequency (e.g., 100 RPM) and vibrator 270 may generate a low frequency vibrations (block 550). In an exemplary implementation, the low frequency vibrations may continue for a short period of time, such as one second to two seconds, or less. The duration of the low frequency vibrations may also be correlated to the duration of time that the low frequency output exceeds target level 430. In each case, the low frequency output of vibrator 270 may be synchronized to low frequency portions of the audio that exceed the predetermined output level (e.g., level 430 in FIG. 4B). This may create an effect to a user of user device 100 that the low frequency vibrations are synchronized with the low frequency portions of the audio output that are more prominent or have a higher output level. For example, music played by user device 100 may include a portion of the music in which a bass drum is playing at a loud level. This portion may correspond to the area labeled 412 in FIG. 4B. Concurrently with the heavy bass drum sound, vibrator 270 may vibrate at a low frequency, thereby creating an effect that the audible tones and vibrations are rhythmically and/or harmonically synchronized.

Continuing with the example above, assume that the alarm-related music (or song) continues to be output by speaker 120. Analysis logic 320 may continue to perform audio spectrum analysis of the output and determine whether the threshold value 430 in either the low or high frequency bands (e.g., 410 or 420) are reached (blocks 520 and 530). In this case, assume that one or more of the frequencies in the high frequency band 420 (labeled 422 in FIG. 4B) exceed threshold level 430. Vibration control logic 330 may then send a signal to vibration mechanism 270 to indicate that vibration mechanism 270 should be vibrated at a high frequency (block 540). For example, vibration control logic 330 may send a signal to motor 350 to rotate the gear coupled to motor 350 at a higher frequency or speed than that described above for the low frequency vibration control trigger. As an example, vibration control logic 330 may signal vibrator 270 to vibrate at a relatively high frequency (e.g., 200 RPM, 250 RPM, etc.), as opposed to the lower frequency described above for the low frequency vibration trigger (e.g., 100 RPM).

In response to the high frequency trigger, motor 350 may rotate the gear associated with vibrator 270 at the high frequency (e.g., 200 RPM) and vibrator 270 may generate high frequency vibrations (block 550). In an exemplary implementation, the high frequency vibrations may continue for a short period of time, such as one second to two seconds, or less. Similar to the discussion above with respect to the low frequency vibrations, music played by user device 100 may include a portion of the music in which a piano is playing treble tones at a loud level. This portion may correspond to the area labeled 422 in FIG. 4B. Concurrently with the loud/heavy piano portion in the higher frequency range, vibrator 270 may vibrate at a high frequency, thereby creating an effect that the audible tones and vibrations are rhythmically and/or harmonically synchronized.

Processing may continue in this manner while the music is being output by speaker 120. That is, low and high frequency vibrations may be generated by vibrator 270 based on the audio spectrum analysis described above. In this manner, the audio and vibrations generated by user device 100 may be synchronized.

In the implementation described above, audio associated with an alarm, such as music or song, is synchronized to the vibrations output by vibrator 270. In other implementations, other types of audio events may be detected and synchronized with the vibrations. For example, in other implementations, ringtones output in response to receiving a telephone call may be synchronized to the vibrations output by vibrator 270. In still other implementations, any audio output, such as music being played by user device 100 may be synchronized with vibrations output by vibrator 270. For example, in some instances, an alarm may include a video or multi-media file that includes audio, such as a music or dialogue. In this case, the audio portion of the video/multi-media file may be synchronized with output by vibrator 270.

Although not described above, in some instances, analysis logic 320 may simultaneously or nearly simultaneously identify both a low frequency trigger and high frequency trigger. In such instances, analysis logic 320 may select either the low frequency or high frequency trigger based on the magnitude of the respective low and high frequency outputs. For example, if the high frequency output is greater (in dB) than the low frequency output, analysis logic 320 may determine that vibrator 270 should vibrate at the high frequency. In other instances, the decision as to which frequency vibration control trigger to generate may be based upon pre-defined or user-defined criteria. For example, analysis logic 320 may pre-store information indicating that in case of both the low and high frequency triggers being identified at the same or nearly the same time, the low frequency vibration may be generated.

### CONCLUSION

Implementations described herein allow a user device to output vibrations that are synchronized to audio that is simultaneously being output by the user device. This may create an effect that enhances the user's experience with respect to receiving notifications of various events, such as alarms, telephone calls, etc. The synchronization may also provide enhanced notification of the event, thereby making it more likely that the user will become aware of the event.

The foregoing description of the embodiments described herein provides illustration and description, but is not intended to be exhaustive or to limit the invention to the precise form disclosed. Modifications and variations are possible in light of the above teachings or may be acquired from the practice of the invention.

For example, aspects have been mainly described above with respect to using a single vibration mechanism that is used to generate vibrations that may be sensed by the user. In other implementations, user device 100 may include two or more vibration units, with one of the vibration units designed to generate low frequency vibrations and the other vibration unit designed to generate high frequency vibrations.

In addition, the implementations described above refer mainly to generating low and high frequency vibrations. In other implementations, more than two frequency bands and corresponding vibration frequencies may be used. For example, a low frequency band, an intermediate frequency band and a high frequency band may be set. In this case, vibrator 270 may be set to vibrate at low, intermediate and high speeds or frequencies based on output of the audio spectrum analysis.

Also, in the implementations described above, a software program executed by processor 220 is used to generate control signals to control motor/gear 350 associated with vibrator 270. In some implementations, processor 220 may signal a power supply to supply the appropriate power to drive the vibrator motor/gear 350 at the desired speed (e.g., high speed or low speed) based on the desired vibration frequency.

In addition, the implementations described above refer to performing audio spectrum analysis in real-time as audio is being output by user device 100. In other implementations, vibration control program 300 may pre-store information associated with synchronizing the output of vibrator 270 with the audio. For example, if the audio spectrum associated with a user's wake-up alarm is known based on a previous analysis, vibration control program 300 may store the trigger information associated with generating the appropriate high/low vibration triggers at the appropriate times, and skip the audio spectrum analysis.

Further, aspects have been described above with respect to synchronizing audio output with vibrations generated by vibrator 270. In other implementations, other types of haptic output that may be sensed by a user may be synchronized to the audio output.

Still further, in some implementations, a user may customize vibration control program 300 to synchronize vibrations with the audio for certain events, such as ringtones associated with particular callers, a morning wake-up alarm, but not for an afternoon alarm, etc. In still other instances, the audio portion of an alert/event (e.g., ringtone) may be muted, while the vibration alert may be output.

Still further, while series of acts have been described with respect to FIG. 5, the order of the acts may be varied in other implementations consistent with the invention. Moreover, non-dependent acts may be performed in parallel.

It will also be apparent to one of ordinary skill in the art that aspects of the invention, as described above, may be implemented in computer devices, cellular communication devices/systems, media playing devices, methods, and/or computer program products. Accordingly, aspects of the present invention may be embodied in hardware and/or in software (including firmware, resident software, micro-code, etc.). Furthermore, aspects of the invention may take the form of a computer program product on a computer-usable or computer-readable storage medium having computer-usable or computer-readable program code embodied in the medium for use by or in connection with an instruction execution system. The actual software code or specialized control hardware used to implement aspects consistent with the principles of the invention is not limiting of the invention. Thus, the operation and behavior of the aspects were described without reference to the specific software code—it being understood that one of ordinary skill in the art would be able to design software and control hardware to implement the aspects based on the description herein.

Further, certain portions of the invention may be implemented as “logic” that performs one or more functions. This logic may include hardware, such as a processor, a microprocessor, an ASIC, an FPGA or other processing logic, software, or a combination of hardware and software.

It should be emphasized that the term “comprises/comprising” when used in this specification is taken to specify the presence of stated features, integers, steps, or components, but does not preclude the presence or addition of one or more other features, integers, steps, components, or groups thereof.

No element, act, or instruction used in the description of the present application should be construed as critical or essential to the invention unless explicitly described as such. Also, as used herein, the article “a” is intended to include one or more items. Further, the phrase “based on,” as used herein is intended to mean “based, at least in part, on” unless explicitly stated otherwise.

The scope of the invention is defined by the claims and their equivalents.

What is claimed is:

1. A method, comprising:
analyzing audio that is output by a first device;
determining, for a first portion of the audio having a first range of frequencies, whether output associated with one of the first range of frequencies is greater than a first threshold value;
determining, for a second portion of the audio having a second range of frequencies, whether output associated with one of the second range of frequencies is greater than a second threshold value;
outputting, by the first device, vibrations having a first frequency in response to determining that the output associated with one of the first range of frequencies is greater than the first threshold value; and
outputting, by the first device, vibrations having a second frequency in response to determining that the output associated with one of the second range of frequencies is greater than the second threshold value.

2. The method of claim 1, wherein the first frequency is lower than the second frequency.

3. The method of claim 1, wherein the first range of frequencies is lower than the second range of frequencies.

4. The method of claim 3, wherein the determining whether output associated with one of the first range of frequencies is greater than a first threshold value comprises:
identifying whether output associated with one of the first range of frequencies reaches or exceeds a predetermined decibel value.

5. The method of claim 4, wherein the determining whether output associated with one of the second range of frequencies is greater than a second threshold value comprises:
identifying whether output associated with one of the second range of frequencies reaches or exceeds the predetermined decibel value.

6. The method of claim 1, further comprising:
generating a first vibration trigger in response to determining that audio output within the first range of frequencies is greater than the first threshold value; and
generating a second vibration trigger in response to determining that audio output within the second range of frequencies is greater than the second threshold value, wherein the first threshold value is equal to the second threshold value.

7. The method of claim 6, further comprising:
controlling a vibrator motor to rotate at a first speed for a first period of time in response to the first vibration trigger; and
controlling the vibrator motor to rotate at a second speed for a second period of time in response to the second vibration trigger, wherein the first speed is different than the second speed.

8. The method of claim 1, wherein the audio comprises a song, a ringtone, an alarm, or an audio portion of a video file.

9. The method of claim 8, wherein the device comprises a mobile terminal.

10. A device, comprising:
a speaker configured to output audio signals;
at least one vibration device; and
logic configured to:
perform audio spectrum analysis associated with the audio signals, and
synchronize output of the at least one vibration device with the audio signals output by the speaker based on the audio spectrum analysis, and
wherein the at least one vibration device is configured to vibrate at a plurality of different frequencies based on the audio spectrum analysis.

11. The device of claim 10, wherein when synchronizing output, the logic is configured to:
determine, for a first portion of the audio spectrum having a first range of frequencies, whether an output associated with one of the first range of frequencies has at least a first output level,
determine, for a second portion of the audio spectrum having a second range of frequencies, whether an output associated with one of the second range of frequencies has at least a second output level,
transmit a first signal to the at least one vibration device in response to determining that an output associated with one of the first ranges of frequencies has at least the first output level, and
transmit a second signal to the at least one vibration device in response to determining that an output associated with one of the second ranges of frequencies has at least the second output level.

12. The device of claim 11, wherein the at least one vibration device comprises a first vibration device, the first vibration device being configured to:
vibrate at a first frequency for a first duration of time in response to the first signal, and
vibrate at a second frequency for a second duration of time in response to the second signal, wherein the second frequency is higher than the first frequency.

13. The device of claim 12, wherein the first and second durations of time are based on the audio spectrum analysis.

14. The device of claim 13, wherein the first range of frequencies is lower than the second range of frequencies.

15. The device of claim 11, wherein the first output level corresponds to a predetermined decibel value, and the second output level corresponds to the predetermined decibel level.

16. The device of claim 10, wherein the at least one vibration device comprises:
a first vibration device including a motor, wherein the motor is configured to:
rotate at a first speed in response to a first vibration trigger that is generated based on the audio spectrum analysis, and
rotate at a second speed in response to a second vibration trigger that is generated based on the audio spectrum analysis, wherein the first speed is slower than the second speed.

17. The device of claim 10, wherein the logic is configured to perform the audio spectrum analysis in real-time.

18. The device of claim 10, wherein the at least one vibration device comprises:
a first vibration device configured to vibrate at a first frequency based on the audio spectrum analysis, and
a second vibration device configured to vibrate at a second frequency based on the audio spectrum analysis, wherein the second frequency is greater than the first frequency.

19. The device of claim 10, wherein the audio signals comprise an alarm, a song, music or a ringtone and the device comprises a mobile terminal.

20. A computer-readable memory device having stored thereon sequences of instructions which, when executed by at least one processor, cause the at least one processor to:
perform audio spectrum analysis associated with audio signals output by a device;
generate a first vibration trigger based on the audio spectrum analysis, the first vibration trigger corresponding to an audio output within a first band of frequencies that has exceeded a predetermined level;
generate a second vibration trigger based on the audio spectrum analysis, the second vibration trigger corresponding to an audio output within a second band of frequencies that has exceeded the predetermined level; and
forward the first and second vibration triggers to a vibration unit within the device.
